(19) United States
(12) Patent Application Publication
(10) Pub. No.: US 2022/0179501 A1
(43) Pub. Date: Jun. 9, 2022

(54) PROCESSING PRESSES OF EXTERNAL KEYBOARD FUNCTION KEYS ACCORDING TO CONFIGURATION OF INTERNAL KEYBOARD FUNCTION KEYS

(71) Applicant: Hewlett-Packard Development Company, L.P., Spring, TX (US)

(72) Inventor: Wen-Cheng Chuang, Taipei City (TW)

(73) Assignee: Hewlett-Packard Development Company, L.P., Spring, TX (US)

(21) Appl. No.: 17/442,972

(22) PCT Filed: Jul. 23, 2019
(86) PCT No.: PCT/US2019/043034

§ 371 Date: Sep. 24, 2021

(51) Int. Cl. G06F 3/023

(52) U.S. Cl. CPC G06F 3/0236; G06F 2203/0382; G06F 3/0238

(57) ABSTRACT

A function key scan code is received from an external keyboard communicatively connected to the computing device. The function key scan code corresponds to a function key of the external keyboard having been pressed. Whether function keys of an internal keyboard of the computing device are configured in an action key mode is determined. In response to determining that the function keys of the internal keyboard of the computing device are configured in the action key mode, the function key scan code received from the external keyboard is converted to an action key scan code.

### BACKGROUND

User preference in computing has largely segued from desktop computers to portable computers like laptop and notebook computers. Desktop computers usually do not include integrated displays and keyboards. Rather, the displays and keyboards are external peripheral devices that connect to their host desktop computers wirelessly or in a wired manner. By comparison, portable computing devices such as laptop and notebook computers commonly have integrated displays and keyboards, which are often referred to as internal displays and keyboards.

### BRIEF DESCRIPTION OF THE DRAWINGS

FIG. 1 is a flowchart of an example method for processing an external keyboard's function keys according to the configuration of an internal keyboard's function keys.

FIG. 2 is a flowchart of an example method for processing a function key scan code received from an external keyboard when the external keyboard's function keys have been configured in the same configuration as an internal keyboard's function keys.

FIG. 3 is a flowchart of an example method for processing a function key scan code received from an external keyboard when the external keyboard's function keys have not been configured or are not configurable.

FIG. 4 is a diagram of an example mapping table consistent with actions associated with an internal keyboard's function keys.

FIG. 5 is a diagram of an example mapping table that has been modified consistent with actions associated with an external keyboard's function keys.

FIG. 6 is a diagram of an example computing device.

FIG. 7 is a diagram of an example non-transitory computer-readable data storage medium.

FIG. 8 is a flowchart of an example method.

### DETAILED DESCRIPTION

As noted in the background, laptop and notebook computers are types of portable computing devices that have internal displays and keyboards. Having such integrated displays and keyboards permits their easy transportation for usage wherever users may be, such as at the office, at home, in hotels, and so on. Owing to their portable nature, however, laptop and notebook computers usually have smaller internal displays and keyboards than their external counterparts to which desktop computers are typically connected. Even if portable computing devices have so-called full-size keyboards—i.e., keyboards having keys the same size as their external peripheral device counterparts—there may be fewer keys, and the keys may be spatially arranged to conserve space as opposed to maximize usability.

Therefore, users often connect external displays and keyboards to their portable computing devices, particularly in their customary environments. For example, a user may have an external display and an external keyboard at the office where his or her laptop or notebook computer is primarily used. Such a setup provides the user with the best of both worlds to large degree, affording the user a large display and a full-size keyboard where he or she uses the portable computing device most of the time, along with the ability to easily transport the computer to use elsewhere when needed.

The keyboards of computers have historically included function keys. Before the advent of modern graphical user interfaces (GUIs), function keys were a primary way for users to interact with computers outside of the alphanumeric and punctuation keys also found on keyboards. Function keys are specifically a way to perform programmed functions on a per-application computer program basis, or on an operating system-wide basis. Whereas early computers usually had between ten and twenty-four function keys organized over one or more rows and/or columns alongside the alphanumeric keys of a keyboard, present-day computers having largely settled on twelve function keys organized within a single row above a keyboard's alphanumeric keys.

Function keys are usually labeled numerically along with the prefix “F” or “FN.” For example, from left to right on a modern computer keyboard, be it an external keyboard or an internal keyboard, the function keys may be separately labeled F1, F2, F3, and so on, through F12. Pressing a function key generates a corresponding function key scan code, which is a number or sequence of numbers assigned to the function key. The operating system of the computing device receives or detects the function key scan code, and can either itself perform an associated function, or pass the detected function key scan code to another computer program running on the computer.

As modern GUIs transitioned to the primary way by which users interact with computers, the usage of function keys decreased. Some users do not use the function keys at all, and se them as an anachronistic artifact. However, because function keys have not completely faded from relevance, even portable computing devices like laptop and notebook computers usually still include them, at least because more keyboard-centric users favor portable computers that have function keys.

Because function keys are not being widely used and yet still have to be included in portable computing devices, manufacturers have afforded the function keys with additional capabilities that more users take advantage of. Specifically, most laptop and notebook computers include action labels on their function keys. In an action key mode, pressing the function keys causes the actions associated with the action labels to be performed. Such actions usually include display-related actions, such as increasing or decreasing display brightness; volume-related actions, such as increasing or decreasing volume as well as mute/unmute; and media playback-related actions, such as play/pause, forward, and reverse. Internally, pressing the function keys generates action key scan codes, which are different from the function key scan codes that are otherwise generated when the keys are pressed.

The inclusion of the action key mode has thus resulted in function keys again being more widely used. To large extent, in fact, function keys are usually used in action key mode, as opposed to in a function key mode in which function key scan codes are generated when the keys are pressed—so much so that the action key mode has largely become the default configuration for many laptop and notebook computers. For the occasions in which a user wants to press a function key in function key mode as opposed to in action key mode, keyboards now typically include a function modifier key, which may be labeled as “FN,” for instance. Akin to other modifier keys like the shift, control, and alt keys, the function modifier key is a key that is held down while another key (in this case, a function key) is pressed to modify the key's functionality.

If the current configuration of a keyboard's function keys is the action key mode, pressing a function key by itself generates the corresponding action key scan code, whereas pressing the function key while holding down the function modifier key generates the corresponding function key scan code. The reverse is also true. If the current configuration is the function key mode, pressing a function key by itself generates the corresponding function key scan code, whereas pressing the function while holding down the function modifier key generates the corresponding action key scan code. A user can therefore set the configuration of a keyboard's function keys to action key scan mode or function key scan mode depending on the mode in which the user intends to primarily use the function keys. The inclusion of the function modifier key permits users to still easily access the other mode on a per-function key basis.

A user of a portable computing device like a laptop or notebook computer may thus configure the function keys of the computer's internal keyboard to operate in a desired mode, such as the action key mode as may be the default mode of the internal keyboard's function keys. However, if the user then communicatively connects an external keyboard to the computer, such as in a wired manner like Universal Serial Bus (USB) or in a wireless manner like Bluetooth, the external keyboard's function keys may not operate according to the current configuration of the internal keyboard's function keys. The end result is a less-than-optimal user experience: a user who often switches between a computer's internal keyboard and an external keyboard connected to the computer will experience different functionality when pressing function keys, depending on whether the user is currently using the internal or the external keyboard.

Some external keyboards cannot be programmed to operate in an action key mode as opposed to the function key mode. For example, older keyboards—and even some newer keyboards—may be unable to send action key scan codes. Such keyboards may be identifiable by the lack of action labels on their function keys, and the omission of a function modifier key. Other keyboards may include action labels on their function keys and also include function modifier keys, but may have a default function key configuration that cannot be changed. Still other keyboards may be programmable to change their current function key configuration, but which does not automatically follow the configuration of the internal keyboard's function keys.

Techniques described herein ameliorate these issues associated with function key usage on an external keyboard communicatively connected to a computing device having an internal keyboard of which the function keys are switchably configurable between an action key mode and a function key mode. Presses of the external keyboard's function keys are processed according to the configuration of the internal keyboard's function keys. If the external keyboard's function keys are switchably configurable between action key mode and function key mode, then they can be configured to be in the same configuration as the internal keyboard's function keys. If the external keyboard's function keys are not so configurable, then function key scan codes received from the external keyboard are converted to action key scan codes if the internal keyboard is configured in action key mode.

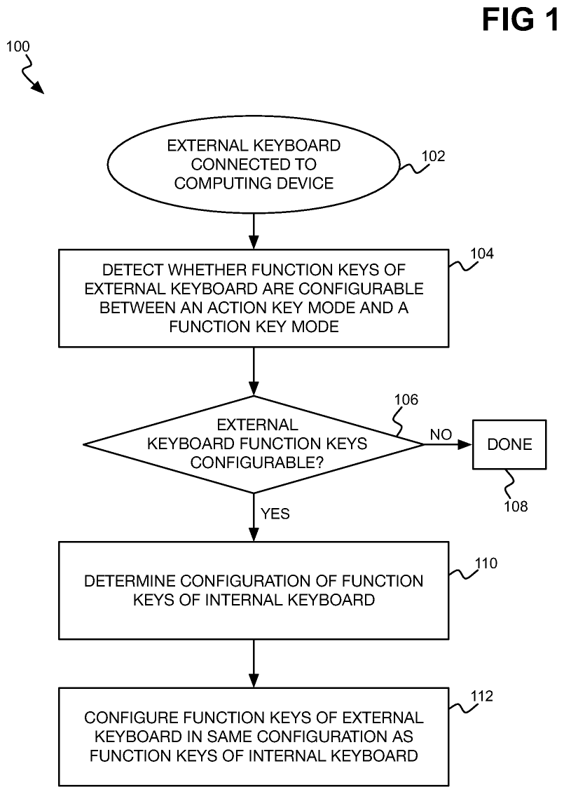

FIG. 1 shows an example method 100 for processing an external keyboard's function keys according to the configuration of an internal keyboard's function keys. The method 100 may be implemented as program code stored on a non-transitory computer-readable data storage medium. A processor can execute the program code. The processor may be a part of a computing device having an internal keyboard with function keys, like a portable computing device such as a laptop or notebook computer.

An external keyboard is communicatively connected to the computing device. The external keyboard may be communicatively connected in a wired manner, such as via USB in the case of a USB keyboard. Such a wired external keyboard can be directly connected to the computing device, via plugging a cable of the external keyboard into an associated port of the computing device. The wired external keyboard may be more indirectly connected to the computing device, such as via plugging the keyboard's cable into an associated port of a hub like a USB hub, which is then itself directly connected to an associated port of the computing device.

The external keyboard may instead be communicatively connected in a wireless manner, such as via Bluetooth in the case of a Bluetooth keyboard. Such a wireless external keyboard is considered as being directly connected to the computing device, and is not connected via a network like an Internet Protocol (IP)-addressable network to which the computing device may be connected via a wired network connection or via a wireless network connection using Wi-Fi. In the case of a Bluetooth keyboard, the wireless external keyboard is connected using a profile in which the keyboard is directly paired with the computing device without the establishment of a network like a personal-area network (PAN). That is, the wireless external keyboard is connected using a human interface device (HID) Bluetooth profile, and not using a network profile like a PAN profile or a local-area network (LAN) access profile (LAP).

The external keyboard may be communicatively connected in a wireless manner in such a way that from the perspective of the computing device the external keyboard is connected in a wired manner. For instance, the external keyboard may have an associated dongle with which the keyboard communicates in a proprietary wireless manner. The dongle may be connected to a USB or other port of the computing device. Therefore, while the external keyboard communicates wirelessly with the dongle, because the dongle is plugged into the computing device (or into a wired hub that is connected to the computing device), from the perspective of the computing device the keyboard communicates in a wired manner.

A keyboard driver, such as a keyboard filter driver, of an operating system running on the computing device can perform the method 100. The keyboard filter driver can be a driver of the operating system that is above the primary keyboard driver of the operating system. The primary keyboard driver may receive scan codes corresponding to key presses on the external keyboard, and pass them to the keyboard filter driver. The keyboard filter driver may in turn modify the scan codes before passing them to an even higher layer of the operating system. Upon receipt of the scan codes, the operating system may itself perform functionality based on the received scan codes, and/or may pass corresponding data to an application program running on the operating system, with the application program then performing functionality. In this way, the keyboard filter driver can control how the external keyboard is used with the computing device.

In the method 100, when the external keyboard is connected to the computing device (102), whether the function keys of the external keyboard are switchably configurable between an action key mode and a function key mode is detected (104). For example, when a wired external keyboard is plugged into the computing device (or into a hub that is itself plugged into the computing device), or when a wireless external keyboard is paired with the computing device, the keyboard may transmit its capabilities and/or its model or type to the computing device. In the former case, the transmitted capabilities may indicate whether the external keyboard can have the configuration of its function keys switched between an action key mode and a function key mode. In the latter case, the computing device may look up the transmitted model or type of the external keyboard to determine whether the keyboard's function keys can be switchably configured between the action key mode and the function key mode.

If the external keyboard's function keys are not switchably configurable between action key mode and function key mode (106), then the method 100 is finished. However, if the configuration of the external keyboard's function keys can be switched between action key mode and function key mode, then the configuration of the function keys of the computing device's internal keyboard is determined (110). For instance, the computing device may have a basic input/output system (BIOS), extensible firmware interface (EFI), unified EFI (UEFI), or other firmware setting indicating the current configuration of the internal key's function keys. When the computing device is booted, the user may be able to press a key combination on the internal keyboard to enter a mode in which such firmware settings can be configured. In another implementation, the current configuration of the internal keyboard's function keys may be configurable within the settings of the operating system itself, such as within the settings of the keyboard filter driver or keyboard driver.

In the action key mode, pressing a function key on the internal keyboard without holding down a function modifier key of the keyboard generates an action key scan code of an action corresponding to the function key that has been pressed. The action is associated with the label printed on the function key itself (i.e., on the top or side of the keycap). For example, the F2 function key may have a label corresponding to a decrease display brightness action. Pressing the F2 function key in the action key mode without holding down the function modifier key causes the hardware of the computing device to generate an action key scan code associated with this action. The action key scan code is not generated by software running on the computing device (such as the operating system). A function key scan code is not generated and subsequently converted to the action key scan code, for instance.

By comparison, pressing a function key on the internal keyboard in the action key mode while holding down a function modifier key generates a function key scan code corresponding to the function key that has been pressed. For example, pressing the F2 function key in the action key mode while holding down the function modifier key causes the hardware of the computing device to generate a function key scan code associated with this function key. The function key scan code is not generated by software running on the computing device (such as the operating system).

In the function key mode, the function keys operate in the opposite way. Pressing a function key on the internal keyboard without holding down a function modifier key generates in hardware a function key scan code corresponding to the function key that has been pressed, without generating any action key scan code that is then converted. Pressing a function key while holding down the function modifier key generates in hardware an action key scan code of the action corresponding to the function key that has been pressed, without first generating a function key scan code that is then converted.

The external keyboard's function keys are configured to be in the same configuration as the function keys of the internal keyboard of the computing device (112). The computing device may communicate to the external keyboard the mode—i.e., the action key mode or function key mode—in which external keyboard should configure its function keys. If the internal keyboard's function keys are configured in the action key mode, then the external keyboard's function keys are likewise configured in the action key mode. Similarly, if the internal keyboard's function keys are configured in the function key mode, then the external keyboard's function keys are likewise configured in the function key mode. If the current configuration of the function keys of the internal keyboard can be changed without rebooting the computing device, then the computing device may reconfigure the external keyboard's function keys each time the internal keyboard's function keys are reconfigured.

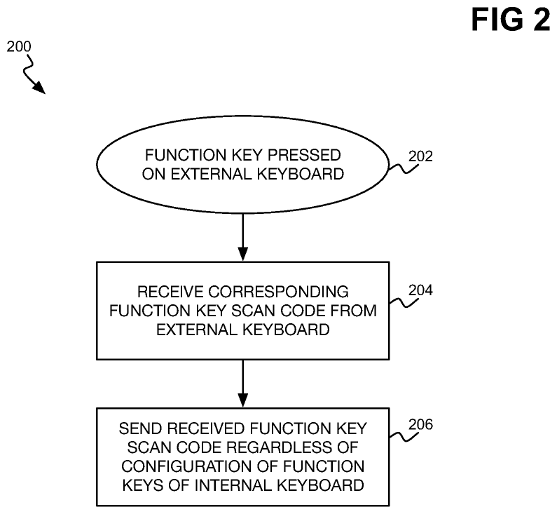

FIG. 2 shows an example method 200 for processing a function key scan code received from the external keyboard when the external keyboard's function keys have been configured in the same configuration as the internal keyboard's function keys per the method 100. Like the method 100, the method 200 can be implemented as program code stored on a non-transitory computer-readable data storage medium and executable by a processor of a computing device having the internal keyboard and the communicatively connected external keyboard. As with the method 100, an operating system running on the computing device, such as a keyboard driver thereof like a keyboard filter driver, can perform the method 200.

In the method 200, a function key has been pressed on the external keyboard (202), which results in the generation of a corresponding function key scan code at the external keyboard. The computing device receives the function key scan code from the external keyboard (204). For instance, a keyboard filter driver may receive the function key scan code from the external keyboard via an intervening lower level keyboard driver. The computing device sends along the function key scan code regardless of the configuration of the internal keyboard's function keys (206), and without performing any conversion of the received function key scan code. For instance, the keyboard filter driver may send the received function key scan code to a higher layer of the operating system.

The function key scan code is sent regardless of the current configuration of the function keys of the internal keyboard because the external keyboard's function keys have already been configured in the same configuration as the internal keyboard's function keys. If the function keys of the external and internal keyboards are in the function key mode, receiving a function key scan code from the external keyboard occurs when the user presses a corresponding function key on the external keyboard without holding down the function modifier key, as would occur if the user were to press the corresponding function key on the internal keyboard without holding down the function modifier key. If the function keys of the external and internal keyboards are in the action key mode, receiving a function key scan code from the external keyboard occurs when the user presses a corresponding function key on the external keyboard while holding down the function modifier key, as would occur if the user were to press the corresponding function key on the internal keyboard without holding down the function modifier key.

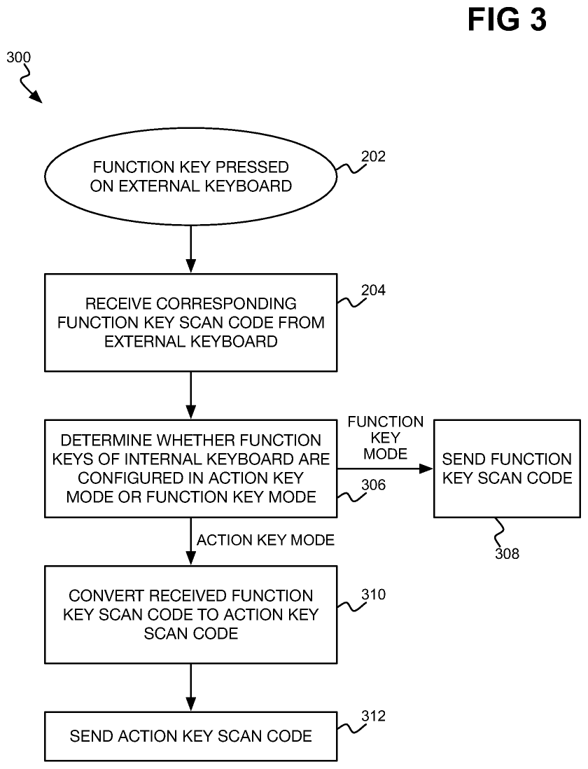

FIG. 3 shows an example method 300 for processing a function key scan code received form the external keyboard when the external keyboard's function keys have not been configured or are not configurable. For instance, if the method 100 was performed prior to the method 300, the function keys of the external keyboard would have been detected in part 104 as not being configurable. Like the methods 100 and 200, the method 300 can be implemented as program code stored on a non-transitory computer-readable data storage medium and executable by a processor of a computing device having an internal keyboard and the communicatively connected external keyboard. As with the methods 100 and 200, an operating system running on the computing device, such as a keyboard driver thereof like a keyboard filter driver, can perform the method 300.

In the method 300, a function key has been pressed on the external keyboard (202), resulting in the generation of a corresponding function key scan code at the external keyboard. The computing device receives the function key scan code (204), as in the method 200. The computing device determines whether the function keys of the internal keyboard are configured in the action key mode or in the function key mode (306). This determination may be made as has been described in relation to part 110 of the method 100.

If the internal keyboard's function keys are configured in the function key mode, then the function key scan code received from the external keyboard is sent (308). The received function key scan code can be sent as has been described in relation to part 206 of the method 200. The received function key scan code is not converted to an action key scan code.

However, if the internal keyboard's function keys are configured in the action key mode, then the function key scan code received from the external keyboard is first converted to an action key scan code (310) before being sent (312). That is, the action key scan code to which the received function key scan code is converted is sent, as opposed to the function key scan code that was generated at the external keyboard. The action key scan code may be sent as has been described in relation to part 206 of the method 200.

By converting function key scan codes received from the external keyboard to action key scan codes, the function keys of the external keyboard are processed consistently with the current configuration of the function keys of the internal keyboard. For example, when the internal keyboard's function keys are in the action key mode, pressing a function key on the internal keyboard without holding down a function modifier key causes an action key scan code to be generated. However, when a function key is pressed on the external keyboard without holding down a function modifier key, a function key scan code is generated.

Therefore, the method 300 converts the function key scan code received from the external keyboard so that the same behavior performed on the external keyboard as on the internal keyboard (pressing function keys without holding down the function modifier key) is processed consistently, with the generation of an action key scan code. In the case of the internal keyboard, an action key scan code is automatically generated in hardware when a function key is pressed without holding down the function modifier key. In the case of the external keyboard, a function key scan code is automatically generated in hardware when a function key is pressed, but the method 300 converts this function key scan code to an action key scan code.

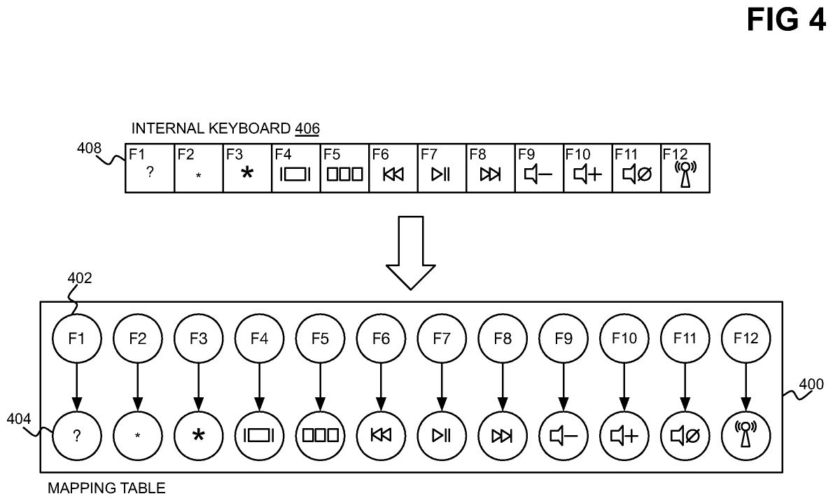

FIG. 4 shows an example mapping table 400 that can be used to convert function key scan codes received from an external keyboard to action key scan codes. The mapping table 400 maps function key scan codes 402 to action key scan codes 404. To convert a function key scan code received from the external keyboard to an action key scan code in part 310, the method 300 looks up the received function key scan code within the mapping table 400 to determine the action key scan code to which the received function key scan code is to be converted.

In FIG. 4, the example mapping table 400 maps function key scan codes 402 to action key scan codes 404 consistent with the actions associated with an internal keyboard 406's function keys 408. For example, the F1 function key 408 has an icon label associated with a help action. Therefore, in the mapping table 400, the function key scan code 402 that is generated when the external keyboard's F1 function key is pressed is converted to the action key scan code 404 associated with the help action. The F2 and F3 function keys 408 have icon labels respectively associated with decrease and increase display brightness actions. Therefore, in the mapping table 400, the function key scan codes 402 that are generated when the external keyboard's F2 and F3 function keys are pressed are respectively converted to the action key scan codes 404 associated with the decrease and increase brightness actions.

The F4 function key 408 of the internal keyboard 406 has an icon label associated with an external display action, such as cycling an attached external display through various modes, including mirroring the internal display, extending the external display, using just the external display, and using just the internal display. Therefore, in the mapping table 400, the function key scan code 402 that is generated when the external keyboard's F4 function key is pressed is converted to the action key scan code 404 associated with this action. The F5 function key has an icon label associated with turning on/off keyboard backlighting. The function key scan code 402 that is generated when the external keyboard's F5 function key is converted to the action key scan code 404 associated with this action.

The F6, F7, and F8 function keys 408 of the internal keyboard 406 have icon labels respectively associated with previous track, play/pause, and next track media actions. In the mapping table 400, the function key scan codes 402 that are generated when the external keyboard's F6, F7, and F8 function keys are pressed are respectively converted to the action key scan codes 404 associated with these media actions. The F9, F10, and F11 function keys of the internal keyboard 406 have icon labels respectively associated with volume decrease, volume increase, and mute/unmute audio actions. In the mapping table 400, the function key scan codes 402 that are generated when the external keyboard's F9, F10, and F11 function keys are pressed are respectively converted to the action key scan codes 404 associated with these audio actions. The F12 function key of the internal keyboard 406 has an icon label associated with turning a Wi-Fi transceiver on/off (i.e., which may be considered an disabling/enabling airplane mode), and thus in the mapping table 400 the function key scan code 402 generated when the F12 function key is pressed on the external keyboard is converted to the action key scan code 404 associated with this action.

Having function key scan codes 402 mapped in the mapping table 400 to action key scan codes 404 in accordance with the actions that are performed when corresponding function keys 408 of the internal keyboard 406 are pressed may be desirable when the external keyboard does not any action labels on its function keys, or when the external keyboard has the same action labels on its function keys. When a function key is pressed on the external keyboard, the resulting function key scan code 402 is converted to the same action key scan code 404 that pressing the same function key on the internal keyboard 406 would generate in action key mode. That is, the action key scan code 404 to which the function key scan code received form the external keyboard is converted in FIG. 4 corresponds to the action associated with the identical function key of the internal keyboard 406.

However, if the external keyboard has different action labels on its function keys, then the mapping of function scan key codes 402 in the mapping table 400 to action key scan codes 404 consistent with the actions associated with the internal keyboard 406's function keys 408 may cause user confusion. For example, if the F11 function key of the external keyboard has an icon label associated with the volume increase action, converting the F11 function key scan code 402 to the mute/unmute action per FIG. 4 can confuse the user, even though the F11 function key 408 of the internal keyboard 406 is associated with the mute/unmute action. Therefore, the mapping table 400 may be modified to change the mapping of the function key scan codes 402 to action key scan codes 404.

The table 400 may be manually modified by the user, such as by accessing a setting of the operating system, like a setting of the keyboard filter driver or other keyboard driver. The table 400 may be automatically modified if the external keyboard transmits its type or model when communicatively connected to the computing device, and the association of actions to the external keyboard's function keys can be determined to correspondingly map the function key scan codes 402 to the action key scan codes 404. Function key scan code 402-to-action key scan code 404 mappings may be individually overridden after such automatic modification occurs.

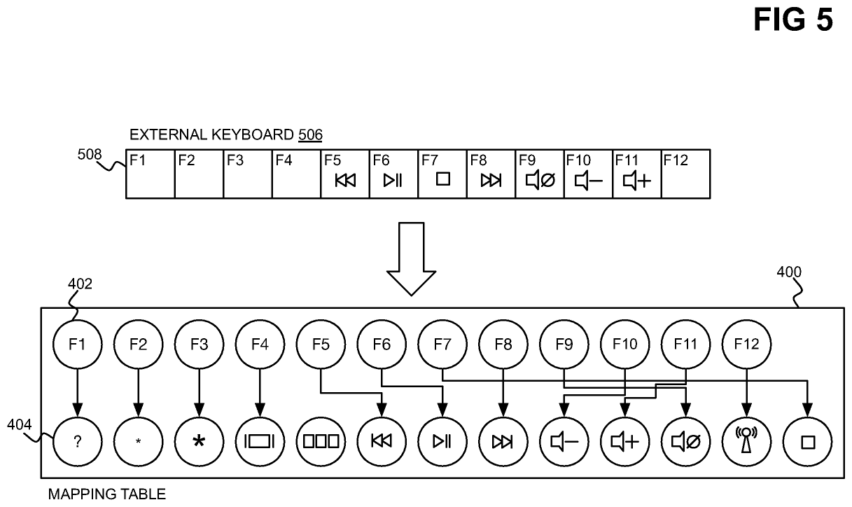

FIG. 5 shows an example of the mapping table 400 after modification consistent with actions associated with an external keyboard 506's function keys 508. The external keyboard 508 does not have actions associated with its F1, F2, F3, F4, and F12 function keys 508. That is, the external keyboard 508 does not have action icon labels on the F1, F2, F3, F4, and F12 function keys 508. Therefore, in the mapping table 400, the corresponding F1, F2, F3, and F4 function key scan codes 402 may not have their mappings modified, and they remain mapped to the same action key scan codes 404 as in FIG. 4. The F8 function key scan code 402 can also remain mapped to the same action key scan code 404 as in FIG. 4, because the F8 function key 508 of the external keyboard 506 has a next track media action icon label no differently than the F8 function key 408 of the internal keyboard 406 does.

However, the F5, F6, F7, F9, F10, and F11 function key scan codes 402 are mapped to different action key scan codes 404 in FIG. 5 as compared to FIG. 4, so that they are consistent with actions associated with their respective function keys 508 on the external keyboard 506. As an example, the F6 function key scan code 402 is mapped to the next track media action key scan code 404 because the F6 function key 508 has an icon label associated with the next track media action. Prior to this modification, the F6 function key scan code 402 was mapped to the previous track media action key scan code 404 per FIG. 4, because the F6 function key 408 of the internal keyboard 406 has an icon label associated with the previous track media action.

Pressing the F5, F6, F7, F9, F10, and F11 function keys 508 of the external keyboard 506 thus results in the conversion of the resultantly generated function key scan codes 402 to action key scan codes 404 for actions that are different than those with which the F5, F6, F7, F9, F10, and F11 function keys 408 of the internal keyboard 406 are associated. The function key scan codes 402 generated when the F5, F6, F9, F10, and F11 function keys 508 are pressed on the external keyboard 506 are instead converted to action key scan codes 404 corresponding to actions associated with the F6, F7, F11, F9, F10 function keys 408 of the internal keyboard 406. The function key scan code 402 generated when the F7 function key is pressed on the external keyboard 506 is converted to an action key scan code 404 corresponding to a stop audio action, with which no function key 408 of the internal keyboard 406 is associated.

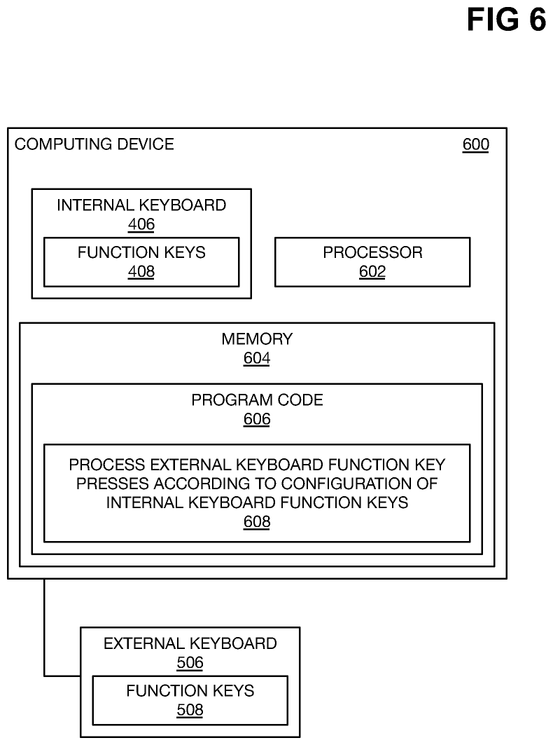

FIG. 6 shows an example computing device 600. The computing device 600 may be a portable computing device, like a laptop or notebook computer, and may include additional hardware components besides those depicted in FIG. 6, such as displays, network hardware, and so on. The computing device 600 includes the internal keyboard 406 having the function keys 408, as well as a processor 602 and a memory 604 storing program code 606. The processor 602 executes the program code 60 to process presses of the function keys 508 of the external keyboard 506 communicatively connected to the computing device 600 according to the configuration of the function keys 408 of the internal keyboard 406.

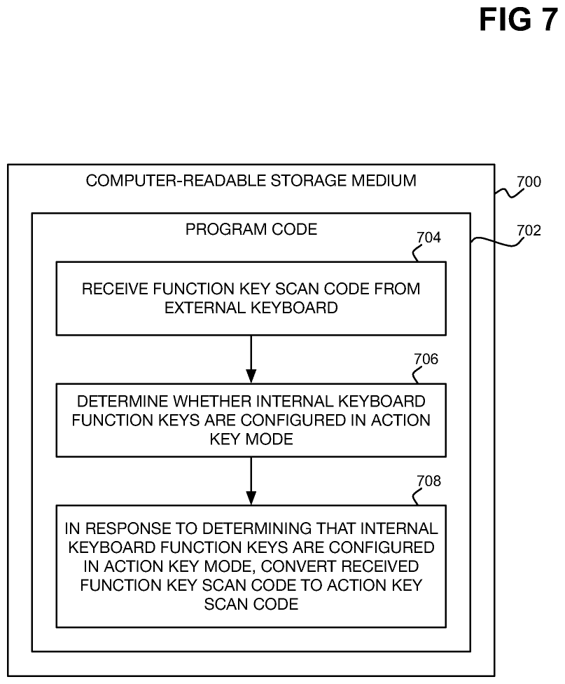

FIG. 7 shows an example non-transitory computer-readable data storage medium 700. The computer-readable data storage medium 700 stores program code 702 executable by a computing device such as a laptop or notebook computer to perform processing. The processing includes receiving a function key scan code from an external keyboard communicatively connected to the computing device (704). The function key scan code corresponds to function key of the external keyboard that has been pressed. The processing includes determining whether function keys of an internal keyboard of the computing device are configured in an action key mode (706). The processing includes, in response to determining that the internal keyboard's function keys are configured in the action key mode, converting the received function key scan code to an action key scan code (708).

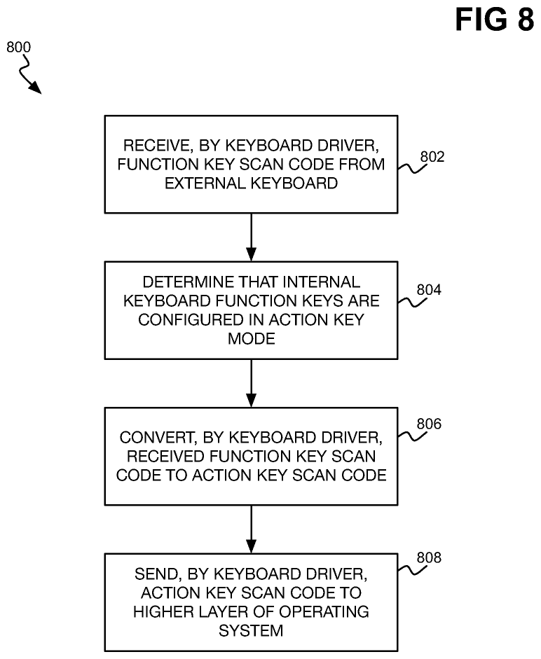

FIG. 8 shows an example method 800. The method 800 includes receiving, by a keyboard driver of an operating system running on a computing device, a function key scan code from an external keyboard communicatively connected to the computing device (802). The function key scan code corresponds to a function key of the external keyboard that has been pressed. The method 800 includes, in response to determining that function keys of an internal keyboard of the computing device are configured in an action key mode, converting, by the keyboard driver, the function key scan code to an action key scan code (804). The method 800 includes sending, by the keyboard driver, the action key scan code to a higher layer of the operating system (806).

Techniques have been described to process presses of the function keys of an external keyboard communicatively connected to a computing device according to the configuration of the function keys of the computing device's internal keyboard. In one implementation, the external keyboard's function keys may be configured to the same configuration as the internal keyboard's function keys. In another implementation, function key scan codes received from the external keyboard are converted to action key scan codes when the internal keyboard's function keys are configured in an action key mode.

We claim:

1. A non-transitory computer-readable data storage medium storing program code executable by a computing device to perform processing comprising:
receiving a function key scan code from an external keyboard communicatively connected to the computing device, the function key scan code corresponding to a function key of the external keyboard having been pressed;
determining whether function keys of an internal keyboard of the computing device are configured in an action key mode; and
in response to determining that the function keys of the internal keyboard of the computing device are configured in the action key mode, converting the function key scan code received from the external keyboard to an action key scan code.

2. The non-transitory computer-readable data storage medium of claim 1, wherein the processing further comprises:
sending the action key scan code to which the function key scan code received from the external keyboard has been converted to an operating system of the computing device.

3. The non-transitory computer-readable data storage medium of claim 1, wherein the processing further comprises:
in response to determining that the function keys of the internal keyboard of the computing device is not configured in the action key mode, sending the function key scan code received from the external keyboard to an operating system of the computing device.

4. The non-transitory computer-readable data storage medium of claim 1, wherein in the action key mode:
pressing of the function keys of the internal keyboard without holding down a function modifier key generates action key scan codes of actions corresponding to the function keys; and
pressing of the function keys of the internal keyboard while holding down the function modifier key generates function key scan codes corresponding to the function keys.

5. The non-transitory computer-readable data storage medium of claim 4, wherein in a function key mode separate from the action key mode:
pressing of the function keys of the internal keyboard while holding down the function modifier key generates the action key scan codes of the actions corresponding to the function keys; and
pressing of the function keys of the internal keyboard without holding down the function modifier key generates the function key scan codes corresponding to the function keys.

6. The non-transitory computer-readable data storage medium of claim 1, wherein the action key scan code to which the function key scan code received from the external keyboard is converted corresponds to an action associated with a function key of the internal keyboard identical to the function key pressed on the external keyboard.

7. The non-transitory computer-readable data storage medium of claim 1, wherein the action key scan code to which the function key scan code received from the external keyboard is converted corresponds to an action associated with a function key of the internal keyboard different than the function key pressed on the external keyboard.

8. A computing device comprising:
an internal keyboard having a plurality of function keys having a configuration switchable between an action key mode and a function key mode;
a processor; and
a memory storing program code executable by the processor to process presses of a plurality of function keys of an external keyboard communicatively connectable to the computing device according to the configuration of the function keys of the internal keyboard.

9. The computing device of claim 8, wherein the program code is executable by the processor to process the function keys of the external keyboard according to the configuration of the function keys of the internal keyboard by:
detecting that the function keys of the external keyboard are switchably configurable between the action key mode and the function key mode; and
in response to detecting that the function keys of the external keyboard are switchably configurable between the action key mode and the function key mode, configuring the function keys of the external keyboard in a same configuration as the function keys of the internal keyboard.

10. The computing device of claim 9, wherein the program code is executable by the processor to process the function keys of the external keyboard according to the configuration of the function keys of the internal keyboard by further:
receiving a function key scan code from the external keyboard, the function key scan code corresponding to one of the function keys of the external keyboard having been pressed; and
sending the function key scan code received from the external keyboard to an operating system of the computing device regardless of whether the function keys of the internal keyboard are configured in the action key mode or the function key mode.

11. The computing device of claim 8, wherein the program code is executable by the processor to process the function keys of the external keyboard according to the configuration of the function keys of the internal keyboard by:
detecting that the function keys of the external keyboard are not configurable between the action key mode and the function key mode;
receiving a function key scan code from the external keyboard, the function key scan code corresponding to a given function key of the external keyboard having been pressed; and
determining whether the function keys of the internal keyboard are configured in the action key mode or the function key mode; and
in response to determining that the function keys of the internal keyboard are configured in the action key mode, converting the function key scan code received from the external keyboard to an action key scan code, and sending the action key scan code to an operating system of the computing device.

12. The computing device of claim 11, wherein the program code is executable by the processor to process the function keys of the external keyboard according to the configuration of the function keys of the internal keyboard by further:
in response to determining that the function keys of the internal keyboard are configured in the function key mode, sending the function key scan code received from the external keyboard to the operating system of the computing device.

13. A method comprising:
receiving, by a keyboard driver of an operating system running on a computing device, a function key scan code from an external keyboard communicatively connected to the computing device, the function key scan code corresponding to a function key of the external keyboard having been pressed;
in response to determining that function keys of an internal keyboard of the computing device are configured in an action key mode:
converting, by the keyboard driver, the function key scan code to an action key scan code; and
sending, by the keyboard driver, the action key scan code to a higher layer of the operating system.

14. The method of claim 13, wherein converting the function key scan code to the action key scan code comprises:
looking up the function key scan code within a table mapping function key scan codes to action key scan codes, to determine the action key scan code to which the action key scan code is to be converted.

15. The method of claim 14, wherein the table has a default mapping in accordance with actions to which the function keys of the internal keyboard correspond,
wherein the default mapping is modifiable to differ from the actions to which the function keys of the internal keyboard correspond.
